(19) United States
(12) Patent Application Publication
(10) Pub. No.: US 2007/0249099 A1
(43) Pub. Date: Oct. 25, 2007

(54) Method of and Apparatus for Manufacturing Elements

(75) Inventor: Robert James Foulger, Essex (GB)

Correspondence Address: VENABLE LLP, P.O. BOX 34385, WASHINGTON, DC, 20043-9998, US

(73) Assignee: E2V Technologies (UK) Limited, Chelmsford, Essex (GB)

(21) Appl. No.: 10/594,230

(22) PCT Filed: Mar. 24, 2005
(86) PCT No.: PCT/GB05/01178

§ 371 Date: Jul. 2, 2007

(30) Foreign Application Priority Data
Mar. 24, 2004 (GB) 0406639.5

(51) Int. Cl. H01L 21/00

(52) U.S. Cl. 438/121

(57) ABSTRACT

A method of separating individual elements (e.g. conducting preforms or Gunn diodes) from an array of such elements comprises the application of energy (e.g. electric current) via a pick-up tool to melt tabs which hold the element to a supporting structure.

The present invention is concerned with a method of manufacturing small elements. The preferred embodiments of the invention are particularly suitable for the manufacture of small (chip scale) components or microcomponents. The typical chip-scale component size is in the range 0.2 mm to a few mm with features of down to 0.01 mm. The term microcomponent is typically used to describe components which are not visible without the use of an optical microscope (e.g., typically within size range of 10⁻⁴ and 10⁻⁷ metres). Micro-components may be used in micro-structural devices.

Electronic microcomponents are typically made as arrays of components on a silicon substrate. It is more efficient to make a number of elements on the same substrate. The processes for creating an array of elements are well known and include, for example, photolithography. The microcomponents are formed as an array of connected elements which are separated from each other before being used.

U.S. Pat. No. 5,824,595 discusses a method in which an array of electronic elements are created on a silicon substrate, and the elements are separated from each other by etching of the substrate.

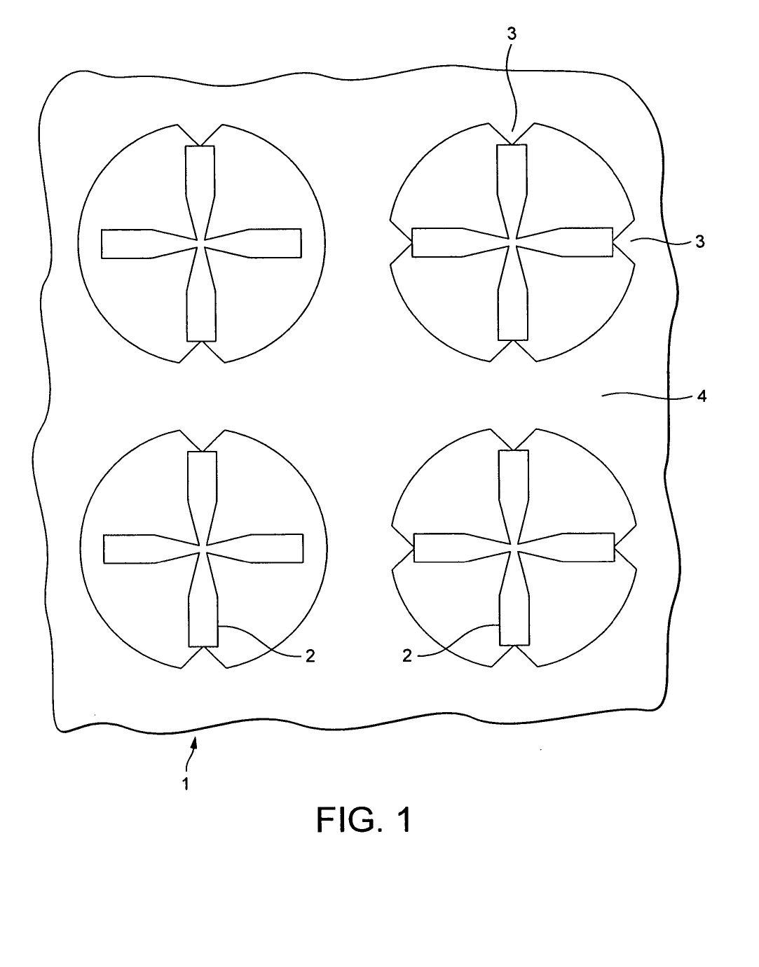

A problem with the etching process disclosed in U.S. Pat. No. 5,824,595 is that separate elements end up loose having been etched from the carrier. Due to their small size, they are prone to clump together and are difficult to separate without damage. There is therefore a low yield. For example, the typical yield for the separation of cross-shaped gold bonding preforms of the type shown in FIG. 1 and used to provide an electrical connection from a semiconductor to other components is only about 20%. Another problem is that any traceability of individual elements is lost when the elements are separated.

The present invention provides method and apparatus as defined in independent claims 1, 2 and 4. Preferred features of the invention are set out in the dependent claims.

Preferred embodiments of the present invention allow one to remove components or elements one at a time in a controlled and/or controllable manner. This means that it is possible to prevent the formation of a mass or conglomerate of mixed up components.

Traceability of individual elements is also improved as the array format is kept right up to the point where an individual part or element is used. This means that a user or a system can determine and/or monitor which particular element or component is taken from where and then where it is placed.

Preferred embodiments of the invention will now be described, by way of example only, with reference to the attached figures in which:

FIG. 1 illustrates a plan view of a portion of an array of elements prior to the separation into discrete components;

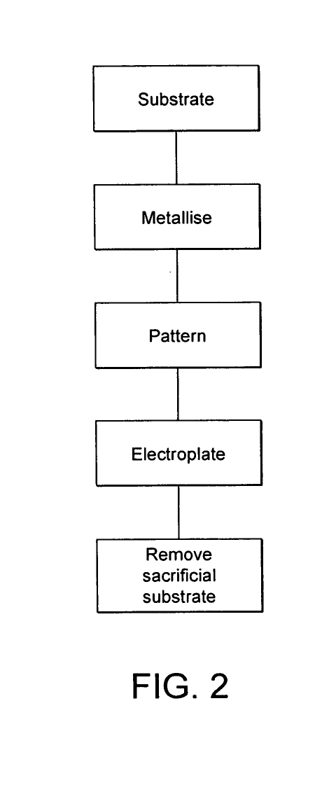

FIG. 2 illustrates a method for manufacturing the array of electronic elements of FIG. 1;

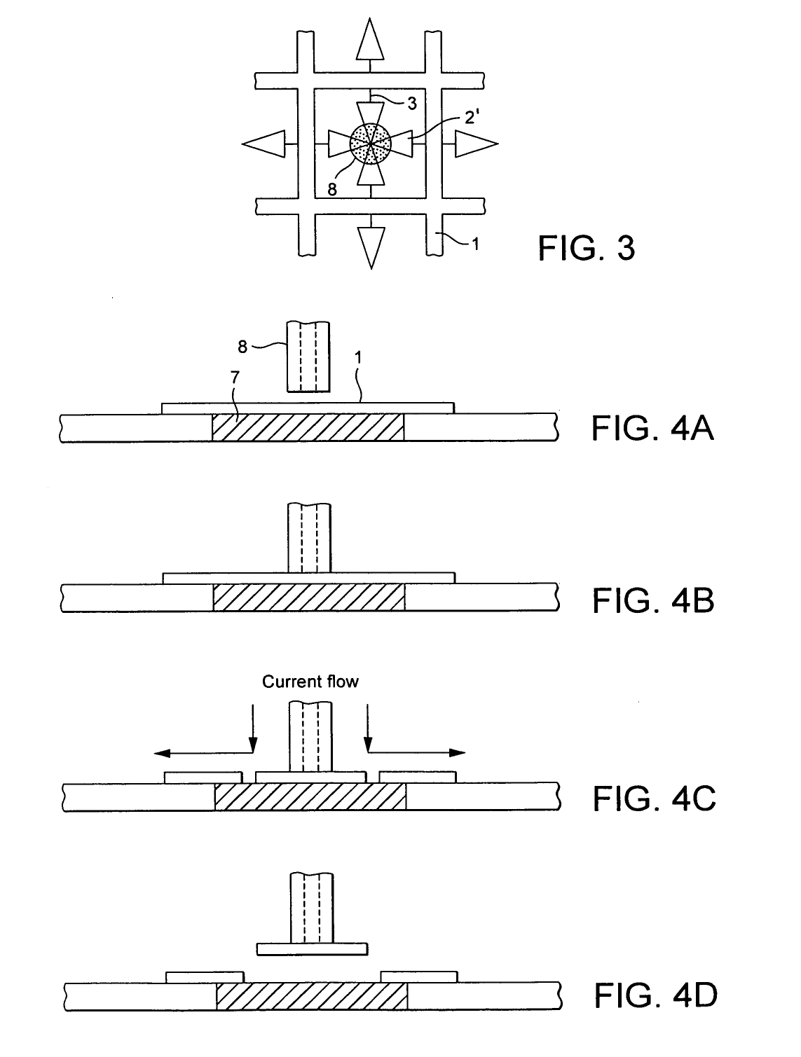

FIG. 3 is a schematic plan view of an array of elements having a pick-up tool positioned over one of the array's elements;

FIGS. 4a to 4d illustrate a separation method embodying the invention for separating an element from the array of FIG. 1 or 3 using the pick-up tool;

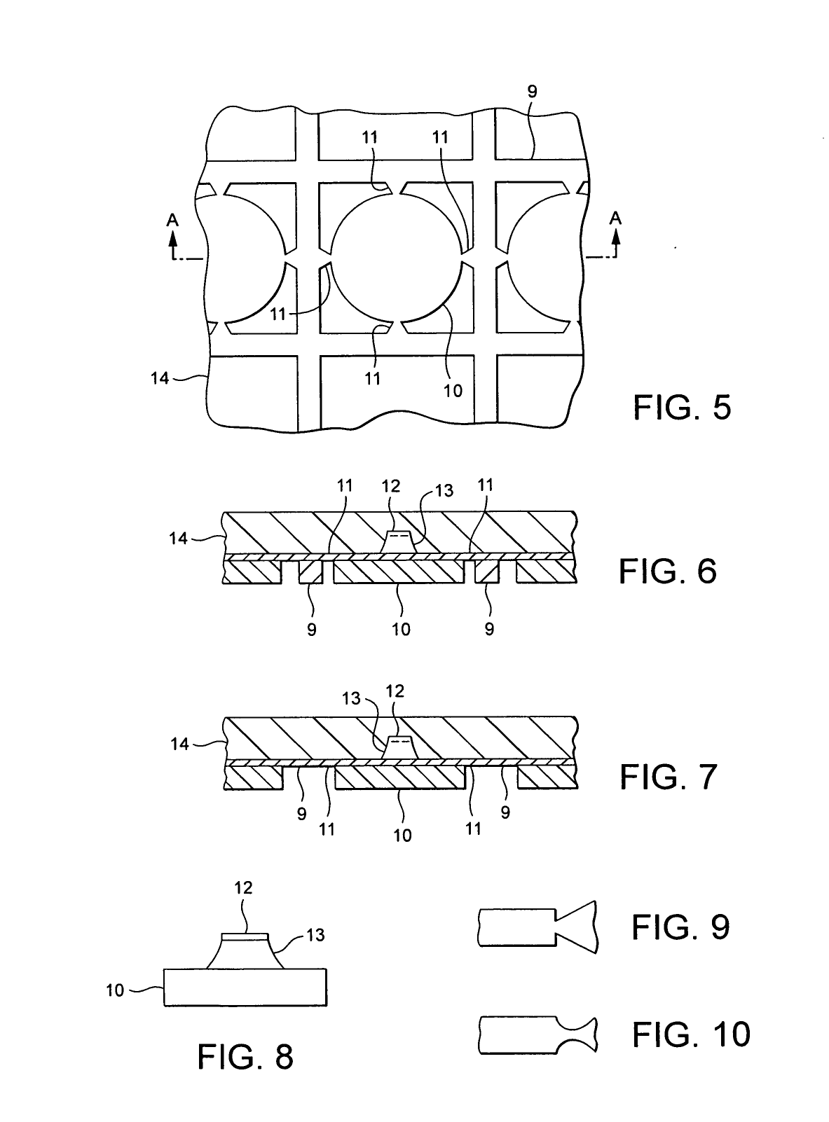

FIG. 5 illustrates a plan view of a portion of a second array of elements prior to separation into discrete components;

FIG. 6 is a section taken on the lines A-A of FIG. 5 in a first form of the second array;

FIG. 7 is a section taken on the line A-A of FIG. 5 in a second form of the second array;

FIG. 8 is a schematic view of a Gunn diode forming an element of the array of FIG. 5;

FIG. 9 is an enlarged view of a connection between an element of the array of FIG. 1 and its associated tab;

FIG. 10 is an enlarged view of an alternative form of a connection between an element of the array of FIG. 1 and its associated tab;

FIG. 11 illustrates a plan view of a portion of a third array of elements prior to separation into discrete components;

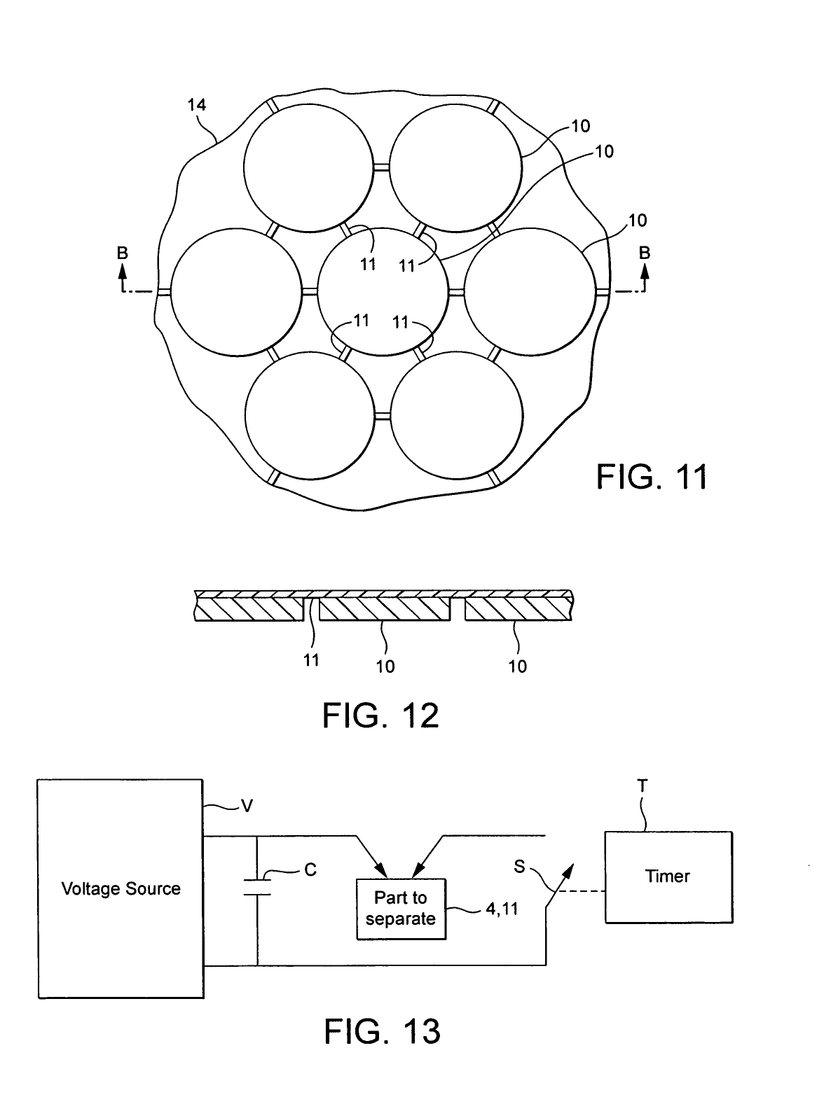

FIG. 12 is a section taken along the line B-B of FIG. 11; and

FIG. 13 is a circuit diagram of one form of means for passing a current through electrically conductive tabs.

FIG. 1 illustrates an array 1 of gold bonding preforms 2 of the type used to provide an electrical connection from a semiconductor die to other current components. Each preform 2 has a Maltese cross like shape with the ends of each cross being connected by a tab 3 to a framework 4 which holds the elements 3 in place until they are separated from the framework.

An array 1 of connected components 2 may be (see FIG. 1) made by deposition on a sacrificial substrate 5 (see FIG. 2). First a metal seed layer of, for example, gold is vacuum deposited on a sacrificial substrate of, for example, silicon. A pattern matching the desired shape of the inter-connected array of components (see FIG. 1) is defined in the seed layer by photolithography and/or chemical etching. A conductive material such as gold is then deposited in the defined pattern in the seed layer by electroplating through a photoresist mask. This is a known process.

In the known processes such as that described in U.S. Pat. No. 5,824,595 the individual elements in the array of elements are then separated by a chemical etching processes. This results in a jumble of elements and the disadvantages discussed above.

In the embodiment of the invention illustrated in FIG. 3, the element 2′ to be separated from the array 1 is positioned on an insulating area 7 underneath an electrically conductive pick-up tool 8. The pick-up tool 8 is brought into contact with and grips the selected element 2. An electrical current is then passed through the pick-up tool 8 and element 2′ to the element holder or framework by way of tabs 4 holding the element in the array. The current heats up the tabs 3 thereby causing them to melt and free the element 2′. The pick-up tool 8 then lifts the separated element 2′ from the array 1. The pick-up tool 8 may then place the element 2′ in an element store or directly on a structure or component of which the element is to form a part.

Embodiments of the invention are concerned with the selective and controllable application of energy to selected tabs so as to allow the separation of a selected or selected elements from an array of inter-connected elements. In an alternative embodiment of the invention having non-conductive tabs, the tabs may be removed, for example, by a blade or by laser ablation.

In the embodiment described with reference to FIGS. 1 to 4, the element to be separated from an array is a conducting preform 2 designed to provide an electrical connection to a semiconductor die. The invention is, however, applicable to any components formed in arrays of components. It is therefore also of application to the separation of the semiconductor die itself, which is subject to the same problem in production as the preforms, namely, difficulty in handling the diodes when individually separated. As an example of the use of the invention in connection with the manufacture of semiconductor components, we shall now describe further embodiments of the invention concerned with arrays of Gunn diodes. As mentioned above, the invention is, however, equally applicable to arrays of other elements or components.

As currently manufactured, the process for manufacturing a Gunn diode begins with a semiconductor wafer on which epitaxial layers are grown, which is metallised to provide a bonding layer for subsequent plating. Heat sinks are plated onto the metallised layer, the wafer is then etched from the other side to thin it, and gold contacts are plated onto the other side of the thinned wafer in register with the heat sinks. The individual Gunn diodes are then etched to form a mesa, and are then separated from each other.

In accordance with embodiments of the invention, this process is modified to improve the ability to handle the Gunn diodes after the separation process. Thus, after the wafer with epitaxial layers is metallised, and the areas are suitably defined by means such as a photoresist mask, an additional layer of gold is plated on by, for example, electroplating, in order to form a mesh 9 together with a first layer of heat sink 10 (only one being indicated by a reference numeral) for the Gunn diodes and tabs 11 (only four being indicated by a reference numeral) for joining the heat sinks of the Gunn diodes to the mesh. In a first form of the second array shown in FIG. 6, this first plating step is followed by a second step (which may also be electroplating) in which the full thickness of the heat sinks 10 of the Gunn diodes is built up and the mesh 9 is built to the same thickness, leaving the tabs 11 at the thickness in the first plating step. In a second form of the second array, the mask is defined so that only the heat sinks 10 for the Gunn diodes are built up, both the mask 9 and the tabs 11 remaining as in the first plating step.

A typical manufactured and separated Gunn diode is shown in FIG. 8, and consists of gold heat sink 10 and gold top contact 12, and semiconductor material 13 in between. In FIGS. 6 and 7, one such finished Gunn diode is shown dotted, in the thickness of the semiconductor material 14.

A suitable thickness for the first plated layer is between 5 and 10 μm (microns), for example, 6 μm (microns), and for the total thickness of both layers between 30 and 50 μm, for example, 40 μm.

In use, the tabs are broken to separate the individual Gunn diodes, and this may be done mechanically, for example, with a blade, by laser, or electrically.

In the case of mechanical separation, the variant of FIG. 6 may be advantageous to promote breakage at the tabs 11.

In the case of electrical separation, the tabs 3 of FIG. 1 may be as shown on a larger scale in FIG. 9 or 10. The smoothly curving neck shown in FIG. 11 is liable to lead to cleaner electrical separation. The tabs of FIG. 5 may also be as shown in either of these FIG. 9 or 10.

A suitable circuit for applying a pulse of current, through a pick-up tool 8 of the type described above, to melt the tabs 3 surrounding the preform 2 of FIG. 1, or the tabs 11 surrounding the heat sinks 10 of FIGS. 5 or 11 is shown in FIG. 13. Capacitor C, which is charged by voltage source V under the control of timer T via switch S, discharges when switch S is operated, through the set of four tabs 3 or 11 to melt them. A current of the order of amps may be necessary to melt a layer thickness of 5 to 10 μm, with a neck thickness in the layer (at its narrowest point) of less than 10 μm. There could, of course, be more or less than the four tabs shown in the embodiments of FIG. 1, 5 or 11. The number of tabs may vary, depended on the mechanical strength required to hold the array together.

It may be found convenient to step repeatedly the finished wafer to bring the next Gunn diode to be separated over a workstation provided with means to connect one pole of the capacitor to the heat sink of the Gunn diode to be separated, the other pole being in electrical contact with the mesh 9.

While the mesh 9 is shown in FIG. 5 as being square-sided, it could surround each Gunn diode with a circular aperture instead. In fact, the most efficient packing density is possible if each Gunn diode is surrounded by six further Gunn diodes with circular mesh apertures.

Further, it is possible to dispense with the mesh 9 altogether, so that the heat sinks are connected to each other by the tabs only. This would be possible for the arrangement shown in FIG. 5, but is also possible for the most efficient packing density situation referred to. This is shown in FIGS. 11 and 12, in which the tabs are shown schematically, but could be, for example, of the shape shown in FIG. 10. Such an arrangement requires a two-stage plating process, the first for the tabs and the first part of the heat sink layer, and the second to build up the thickness of the heat sinks. The thickness of the layers and the means for separating the layers may be as for the embodiment of FIGS. 5 to 7.

1. A method of manufacturing a number of discrete elements, comprising the steps of manufacturing an array of said discrete elements wherein each element is attached to a supporting structure and/or at least one other element by a support tab, and selectively removing or breaking the tab or tabs supporting a particular element or particular elements.

2. A method of manufacturing a number of Gunn diodes, comprising the steps of manufacturing an array of Gunn diodes wherein each Gunn diode is attached to a supporting mesh and/or at least one other Gunn diode by a support tab, and selectively removing or breaking the tab or tabs supporting a particular Gunn diode or particular Gunn diodes.

3. A method according to claim 1 wherein the tab or tabs are electrically conductive and are removed or broken by passing a current therethrough.

4. Apparatus for separating a selected element of selected elements from an array of inter-connected elements including a first portion capable of removing or breaking the connection or connections between a selected element and its neighbouring element or elements, and a second portion capable of picking up or otherwise removing the selected element or elements.

5. Apparatus according to claim 4 wherein the second portion includes means for applying energy to the connection or connections.

6. Apparatus according to claim 5 including means for causing a current to flow through the connection or connections.

7. Apparatus according to claim 4, wherein the selected element or selected elements are Gunn diodes.

8. Apparatus according to claim 4, wherein the connection or connections are electrically conductive and including means to break the connection or connections by passing a current therethrough.

9. Apparatus according to claim 4, wherein the element or elements comprise a preform of Maltese cross-like shape.
